(19) United States
(12) Patent Application Publication
(10) Pub. No.: US 2003/0178641 A1
(43) Pub. Date: Sep. 25, 2003

(54) Microfluidic platforms for use with specific binding assays, specific binding assays that employ microfluidics, and methods

(76) Inventors: Steven M. Blair, Salt Lake City, UT (US); Layne Daryl Williams, Salt Lake City, UT (US)

Correspondence Address: TRASK BRITT, P.O. BOX 2550, SALT LAKE CITY, UT, 84110, US

(21) Appl. No.: 10/350,361

(22) Filed: Jan. 23, 2003

Related U.S. Application Data
(60) Provisional application No. 60/351,261, filed on Jan. 23, 2002.

(51) Int. Cl. H01L 31/0328

(52) U.S. Cl. 257/200

(57) ABSTRACT

A microfluidic platform for use with a specific binding assay apparatus includes an elongate, nonlinear channel through which a sample or sample solution may flow to be brought into contact with capture molecules immobilized relative to a number of sensing zones on a reaction surface of the specific binding assay apparatus. The microfluidic platform may include regions with enlarged widths, which are to be positioned adjacent to and in communication with sensing zones of the specific binding assay apparatus. In addition, the microfluidic platform may include mixing structures that protrude into the channel so as to create folding of and, thus facilitate mixing of the constituents of a sample solution as the sample solution flows through the channel. Specific binding assay apparatus that include microfluidic platforms thereon are also disclosed. In addition, methods for fabricating the microfluidic platform are also disclosed, as are methods for using the microfluidic platform.

### CROSS-REFERENCE TO RELATED APPLICATION

Under the provisions of 35 U.S.C. §119(e), priority is claimed from U.S. Provisional Application Serial No. 60/351,261, filed on Jan. 23, 2002.

### BACKGROUND OF THE INVENTION

1. Field of the Invention

The present invention relates generally to specific binding assays and, more specifically, to specific binding assay formats for analyzing very small samples or sample solutions. In particular, the present invention relates to specific binding assays that employ microfluidics to convey small samples or sample solutions across a number of different sensing zones and to microfluidic platforms for use with specific binding assays, as well as to methods for fabricating such microfluidic platforms and specific binding apparatus that include such microfluidic platforms.

2. Background of Related Art

A major challenge in many biosensing applications is the real-time detection of a multitude of analytes from a small sample volume. Biological sensing has been an intensely active area of research due to applications in environmental sensing, food testing, and clinical screenings, just to name a few, and may include, for example, assays for cells, viruses, antibodies, proteins or peptides, nucleic acids, drugs, and other molecules of interest.

Many optical techniques have been studied for biosensing applications in which the analyte binds specifically (through an affinity interaction) to a capture molecule immobilized to the surface of a waveguide, and have proven to have relatively high sensitivity and to provide short assay times. These biosensors can be classified into two categories: mass sensors and fluorescence sensors. Mass sensors measure the presence of the captured analyte by detecting changes in absorption or refractive index, but are ineffective for analytes with small molecular weights and are sensitive to both specific binding and non-specific binding. Fluorescence sensors measure the emission from an immobilized tracer molecule or fluorescently-labeled analyte, which is excited by the evanescent field of an optical waveguide, and are generally more sensitive and more specific than mass sensors. Many of the fluorescence approaches are based on the use of evanescent wave excitation from an optical fiber or planar waveguide. Planar wave guides have many advantages over fibers, including larger sensing area, direct extension to multi-analyte array sensing, and support of integrated fluidic channels or flow cells.

Many specific binding, or affinity, biosensing techniques are based on introduction of a sample solution onto a chip or device, where the solution covers substantially the entire device (i.e., all of the sensing zones) and remains stationary during the sensing process. This process is highly inefficient in terms of the use of the sample volume and is the primary reason why molecular amplification steps are often taken in order to increase the sample volume. Molecular amplification, however, takes time and presents an additional step whereby the probability for introducing error into the test is increased. In addition, many existing assay techniques employ a so-called “end point” detection, which requires that the affinity reaction reach completion and, thus, further waiting.

Various approaches have been taken to facilitate the analysis of samples having small volumes. For example, U.S. Pat. No. 5,583,281, issued to Yu on Dec. 10, 1996 (hereinafter “Yu”), and U.S. Pat. No. 4,471,647, issued to Jerman et al. on Sep. 18, 1984 (hereinafter “Jerman”), disclose miniature gas chromatographs that include columns with spiral paths. As is typical with gas chromatographs, the constituent parts of a sample become separated from one another as the sample travels along the length of the column rather than by interaction with one or more reagents at sensing zones located along the length of the column.

Microfluidics have also been used in the analysis of liquid samples. Examples of the this use are provided by U.S. Pat. No. 5,641,400, issued to Kaltenbach et al. on Jun. 24, 1997 (hereinafter “Kaltenbach”), and U.S. Pat. No. 5,571,410, issued to Swedberg et al. on Nov. 5, 1996 (hereinafter “Swedberg”). Kaltenbach and Swedberg both disclose liquid phase sample separation apparatus that include laser-ablated microchannels that take somewhat serpentine paths. These apparatus may be used in electrophoretic separation processes and analytes that have been separated along the lengths of their microchannels may be detected by way of known optical processes (e.g., by measuring the absorbance at one or more particular wavelengths). Neither of these devices would, however, be useful in a real-time, optical, specific binding assay.

U.S. Pat. No. 5,482,598, issued to Isaka et al. on Jan. 9, 1996 (hereinafter “Isaka”), discloses a sample separation apparatus that includes a microchannel formed from porous silicon. This microchannel may have a somewhat spiral path. Again, however, the separation of one or more analytes from a sample is based on the size of each analyte, and the detection of each analyte is not effected until that analyte or a modified form thereof exits the microchannel.

Considerable work involving microfluidics and DNA is being performed. Dobrinski, H, et al., “Flexible Microfluidic-Device-Stamp-System with Integrated Electrical Sensor for Real Time DNA Detection,” 1^{st}Ann. Intern'l IEEE-EMBS Special Topic Conf. on Microtech. in Med. & Biol., pages 33-35 (Oct. 12-14, 2000), describes a DNA sensor that incorporates a silicon-polymer hybrid microfluidic flow cell. That flow cell is configured to spread a sample out over a single reaction area. Capture oligonucleotides within the reaction area are bound to a surface of the flow cell and a sample that includes DNA is flowed over the surface of the flow cell and past the capture oligonucleotides thereon to promote hybridization of the DNA therein with the immobilized capture oligonucleotides. Although detection is performed in real time, impedimetric techniques, rather than optical sensing processes, are employed.

The usefulness of microfluidics with end-point sensors is also being researched. For example, Kuhr et al. have developed an end-point sensor with which DNA may be electrochemically detected. Once analyte DNA has hybridized with capture oligonucleotides and the remainder of a sample solution has been flowed or washed away, the DNA strands are denatured and the previously bound oligonucleotides flow past a set of electrodes. A group at Motorola have developed a polydimethylsiloxane (PDMS) flow cell that sits atop of a DNA array card (i.e., a substrate with nucleotides bound to a plurality of discrete locations thereof). Once hybridization is complete the microfluidics may be removed and the DNA array card placed in a card reader for detection. Thus, that assay is an end-point assay and is, therefore, not useful in providing results in real time.

In view of the foregoing, it appears that there is a need for an apparatus that facilitates the optical assessment of small-volume samples accurately and reliably in real time.

### SUMMARY OF THE INVENTION

The present invention includes microfluidic platforms that are useful with apparatus for conducting specific binding assays. A microfluidic platform incorporating teachings of the present invention includes at least one elongate, nonlinear microfluidic channel that is configured to be positioned over a reaction surface of an apparatus for conducting one or more specific binding assays.

The at least one elongate, nonlinear microfluidic channel of a microfluidic platform according to the present invention may have a substantially uniform width and height along the length thereof. Alternatively, regions of the at least one elongate, nonlinear microfluidic channel that are to communicate with sensing zones of a specific binding apparatus may have an increased width relative to the remaining regions of the channel (i.e., those which will not be in direct communication with a sensing zone). Features that create folding of and that may, therefore, cause mixing of a sample or sample solution upon flowing thereof along the length of a channel may also be provided at one or more surfaces of the channel. Such features may be particularly advantageous when used at or near regions of the channel that will be in direct communication with corresponding sensing zones of a specific binding assay apparatus when the microfluidic platform and specific binding assay apparatus are assembled with one another.

Specific binding assay apparatus that include a microfluidic channel over at least two sensing zones thereof are also within the scope of the present invention. These specific binding assay apparatus may be embodied as any type of specific binding assay apparatus with which microfluidics would be useful. Examples of such apparatus include, but are not limited to, waveguides (including planar and cylindrical waveguides, as well as waveguides having other configurations) and other apparatus (e.g., semiconductor chip-based devices) which employ use of labels (e.g., fluorescent tags, metal tags, etc.), apparatus that are useful in surface plasmon resonance (SPR) type detection, and the like.

In another aspect of the present invention, a method for conducting a specific binding assay includes introducing a sample or sample solution into an open end of a microfluidic channel and permitting the sample or sample solution to be drawn into and through the channel, into contact with a plurality of sensing zones on the surface of a specific binding assay apparatus. As the sample or sample solution is drawn through the channel, binding of analytes in the sample or sample solution by corresponding capture molecules at each sensing zone may then be detected, as known in the art. Detection may be conducted from a location orthogonal to a plane of the specific binding assay apparatus. Of course, detection of binding depends upon the specific type of assay (e.g., immunofluorescence, SPR, etc.) being used.

An exemplary method for fabricating a microfluidic platform includes forming a mold, or master, that includes at least one elongate, nonlinear protrusion. The protrusion follows a path that is substantially identical to a continuous pathway through a plurality of sensing zones on a specific binding assay apparatus with which the microfluidic platform is to be used. The heights and widths of the protrusions may be configured to provide desired fluid flow properties, such as minimum sample or sample solution size, flow rate, and the like. In addition, one or more surfaces of the protrusions may be configured in such a way as to define mixing, or folding-generating, structures in a microfluidic platform formed therewith. A material that will closely conform to the shape of the surfaces of the mold is then introduced onto such surfaces and at least partially cured while located thereon. The material may readily release from the mold upon at least partial curing thereof or, in the alternative, be compatible with a suitable release material. It is currently preferred that the material will polymerize in such a way as to substantially retain the desired shape and dimensions of the at least one microfluidic channel formed therein, as well as the shape and dimensions of any mixing structures formed therefrom, upon being removed from the mold. Subsequent changes to the orientation of the sidewalls of the at least one microfluidic channel, mixing structures, and other features or dimensions of the resulting microfluidic platform are, however, also within the scope of the present invention.

It is currently preferred that the material of the microfluidic platform be substantially impermeable to the types of samples or sample solutions (e.g., aqueous) that will contact the resulting microfluidic platform. It is also currently preferred that at least the assayed constituents (i.e., the analytes) of a sample or sample solution not be adsorbed to or chemically react with the material of the microfluidic platform. The material from which the microfluidic platform is fabricated may prevent such adsorption by or reaction with the constituents of a sample or sample solution, or the microfluidic platform may be treated with passivation chemicals, as known in the art, that will prevent such adsorption or reaction.

In addition, a microfluidic platform incorporating teachings of the present invention may be fabricated from a material that is optically transparent to at least wavelengths of radiation that are indicative of the occurrence of a binding reaction at a sensing zone of a specific binding assay apparatus with which the microfluidic platform is used so as to facilitate detection of binding of one or more types of analytes by corresponding capture molecules through the microfluidic platform. Accordingly, the thickness of the material from which the microfluidic platform is formed may also be optimized to facilitate the level of detection of binding of one or more analytes in a sample or sample solution therethrough.

A microfluidic platform that is fabricated separately from its corresponding specific binding assay apparatus, such as the molded microfluidic platform described herein, may be assembled with the specific binding assay apparatus by aligning the channel with corresponding sensing zones of the specific binding apparatus, the channel and its corresponding sensing zones being in fluid communication with one another, and securing the microfluidic platform and the specific binding assay apparatus to each other. The material of the microfluidic platform may seal directly onto a surface of the specific binding assay or an adhesive or sealant material may be employed.

As an alternative to the use of a mold to fabricate the microfluidic platform, micromachining processes (e.g., those used in semiconductor device fabrication) may be used to directly fabricate a microfluidic platform. Other known processes that would be suitable for fabricating the microfluidic platform are also within the scope of the present invention.

Other features and advantages of the present invention will become apparent to those of ordinary skill in the art through consideration of the ensuing description, the accompanying drawings, and the appended claims.

### BRIEF DESCRIPTION OF THE DRAWINGS

In the drawings, which depict various aspects of exemplary embodiments of the present invention:

FIG. 1 is a bottom view of a microfluidic platform incorporating teachings of the present invention;

FIG. 2 is a cross-section taken along line 2-2 of FIG. 1, showing the microfluidic platform in an upright orientation;

FIG. 3 is a bottom view of an exemplary enlarged region of a channel of a microfluidic platform such as that shown in FIG. 1, depicting an exemplary type of mixing structure that may be used therein;

FIG. 4 is a bottom view of another exemplary enlarged region of a channel of a microfluidic platform such as that shown in FIG. 1, depicting another exemplary type of mixing structure that may be used therein;

FIGS. 5 and 5A are cross-sectional representation taken along line 5-5 of FIG. 1, depicting an examples of the manner in which the enlarged regions of the channel of the microfluidic platform may be configured;

FIGS. 6 through 6B are cross-sectional representations taken along line 6-6 of FIG. 1, showing examples of corrugated surfaces that may be included at the enlarged regions of the channel of the microfluidic platform;

FIGS. 7 through 10 schematically depict an exemplary method by which a microfluidic platform of the invention may be fabricated;

FIG. 11 depicts assembly of a separately formed microfluidic platform with a specific binding assay apparatus;

FIG. 12 is a schematic representation of a specific binding assay apparatus with which a microfluidic platform according to the present invention may be used; and

FIG. 13 is cross-section taken along line 13-13 of FIG. 10.

### DETAILED DESCRIPTION OF THE INVENTION

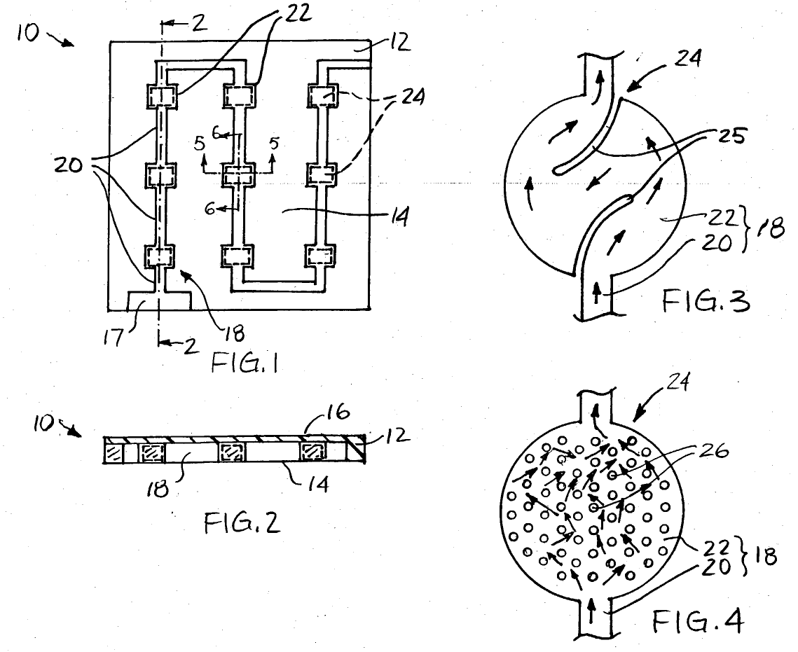

With reference to FIGS. 1 and 2, an exemplary embodiment of microfluidic platform 10 according to the present invention is illustrated. Microfluidic platform 10 includes a substantially planar substrate 12 with opposite first and second surfaces 14 and 16, respectively. First surface 14 includes at least one elongate, nonlinear channel 18 therein and is configured to be secured to a reaction surface 52 of a specific binding assay apparatus 50 (FIGS. 1 and 2), while second surface 16 is depicted as being substantially planar. Microfluidic platform 10 may also include a sample reservoir 17 in communication with an end of channel 18.

As shown in FIG. 1, channel 18 takes a somewhat serpentine path and includes a plurality of transport regions 20 and discrete, enlarged regions 22 along the length thereof, with transport regions 20 being located between adjacent enlarged regions 22. Enlarged regions 22 are positioned along channel 18 so as to communicate with corresponding sensing zones 54 (FIGS. 10 and 11) of specific binding assay apparatus 50 when microfluidic platform 10 and specific binding assay apparatus 50 are mutually positioned in an assembled relationship.

Low cross-sectional microflulidic channels 18 incorporating teachings of the present invention may have dimensions of as small as about 25 μm×t, where t is the channel depth, which may be as small as about 1 μm to about 5 μm or greater. The dimensions and configuration of each channel 18 may be adjusted to provide a particular flow rate and/or binding probability. The expected outcomes of studies using the channels are the minimum number of molecules in solution needed for detection, the minimum sample or sample solution volume that can be used, and the length of time required to introduce the sample or sample solution to each sensing zone of an array of sensing zones of a specific binding assay apparatus.

By way of example only, channel 18 may have a depth, or height, of about 70 μm along substantially the entire length thereof, although other channel depths (e.g., about 25 μm to about 70 μm) are also within the scope of the present invention. Each transport region 20 of channel may have a width of about 250 μm or less (e.g., about 25 μm to about 250 μm), while each enlarged region 22 may have a width of about 1 mm or less (e.g., about 100 μm to about 1 mm).

One or more mixing structures 24 may protrude into channel 18. As depicted, mixing structures 24 may be located at or near (e.g., upstream from) each enlarged region 22 of channel 18. Mixing structures 24 may be configured to create folding in a sample or sample solution as it flows through channel 18 and, thus, cause mixing and homogeneity of the constituents of the sample or sample solution.

FIGS. 3 and 4 depict exemplary configurations of mixing structures 24. In FIG. 3, mixing structures 24 comprise channel walls 25 that create convolutions in channel 18 at an enlarged region 22 thereof. FIG. 4 depicts a mixing structure 24 that includes a group of protrusions 26, or posts, that may have a pin-like or column-like appearance and which are positioned within an enlarged region 22 of channel 18. Alternatively, protrusions 26 may have a conical shape, a frustoconical shape, or another, similar shape with tapered sidewalls. The arrows in FIGS. 3 and 4 illustrate exemplary directions of fluid flow through channel 18 as a sample or sample solution encounters a mixing structure 24. While the mixing structures 24 depicted in FIGS. 3 and 4 include features that extend at least partially along the heights of their respective channels 18, mixing structures with features that extend from the sides of channels 18 are also within the scope of the present invention, as are mixing structures that include combinations of features that extend at least partially along the height and width of a channel 18.

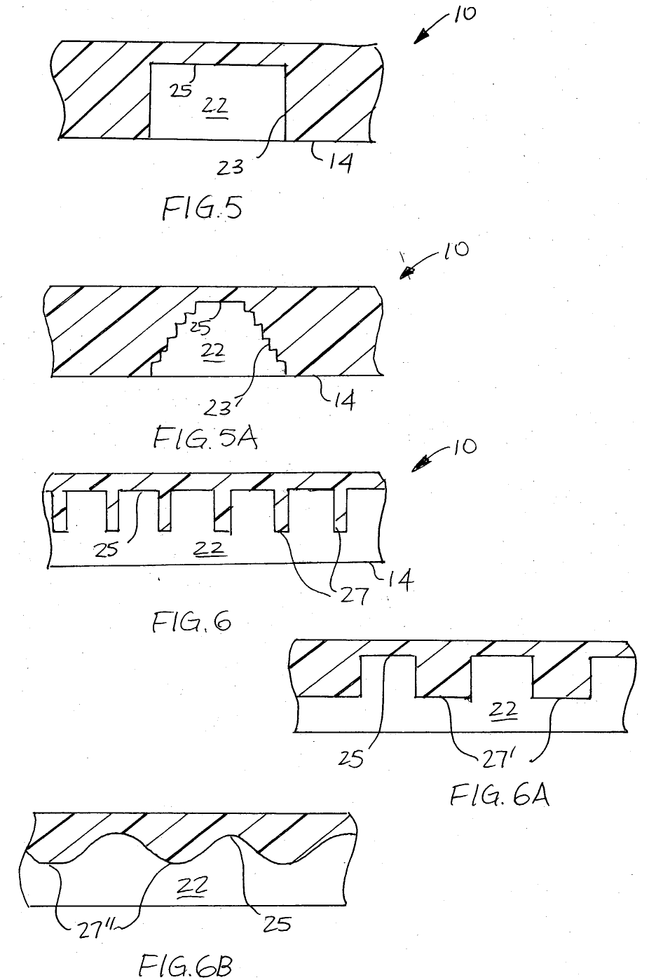

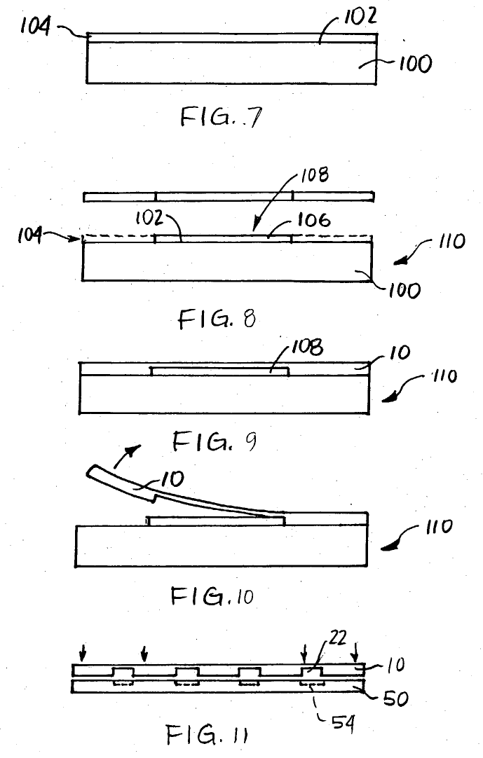

FIGS. 5 through 6B depict various examples of the manner in which enlarged regions 22 of channel 18 may be configured. Specifically, FIGS. 5 and 5A depict examples of the manner in which side walls 23, 23′ of each enlarged region 22 may be oriented. FIGS. 6 through 6B depict exemplary types of corrugation 27, 27′, 27″ that may be employed along a ceiling 25 of at least an enlarged region 22 of a channel 18 of a microfluidic platform that incorporates teachings of the present invention.

As shown in FIG. 5, one or more enlarged regions 22 may include sidewalls 23 that are oriented substantially perpendicular to a major plane of microfluidic platform 10. FIG. 5A illustrates an example of an enlarged region 22 that includes a tapered side wall 23′. While side wall 23′ tapers outwardly from a ceiling 25 of enlarged region 22 to a first surface 14 of microfluidic platform 10 (i.e., enlarged region 22 is smaller at ceiling 25 than at first surface 14), tapering may occur in the opposite direction. Further, while FIG. 5A depicts tapering of side walls 23′ as being substantially linear, such tapering may be stepped and/or curved. Alternatively, an enlarged region 22 may have somewhat convex or concave side walls. These and other nonperpendicular configurations of side walls 23, 23′ may be used either with or without mixing structures 24 (FIGS. 3 and 4).

Nonperpendicular configurations of the side walls 23, 23′ of enlarged regions 22 that are within the scope of the present invention may enhance the reaction kinetics between an analyte in a sample or sample solution and capture molecules 56 of a specific binding assay apparatus 50 (FIGS. 12 and 13) with which microfluidic platform 10 is used. For example, tapering side walls 23′ of enlarged regions 22 in the manner that is shown in FIG. 5A may force a sample or sample solution downward to a location of lesser resistance to flow (i.e., the more open location adjacent to first surface 14 of microfluidic platform 10, thereby increasing the likelihood that analyte therein will contact and, thus, be bound by capture molecules 56 that are exposed to an enlarged region 22 of microfluidic platform 10.

FIGS. 6 through 6B depict various examples of enlarged regions 22 of a channel 18 of a microfluidic platform 10 that incorporates teachings of the present invention with ceilings 25 that comprise corrugations 27, 27′, 27″, respectively. As shown, corrugations 27, 27′, 27″ extend at least somewhat transversely to the direction in which a sample or sample solution will flow through enlarged region 22. Thus, corrugations 27, 27′, 27″ may extend in a direction which is substantially perpendicular to the general direction in which a sample or sample solution will flow through enlarged region 22. Corrugations 27, 27′, 27″ may be linear or they may be somewhat curved, sinusoidal, V-shaped, zig-zagged, or otherwise configured. As shown in FIG. 6, corrugations 27 may comprise elongate members that extend downward from ceiling 25 and substantially across enlarged region 22. FIG. 6A depicts rectangular corrugations 27′ that have a more robust configuration. The corrugations 27″ that are illustrated in FIG. 6B comprise a sinusoidal configuration across ceiling 25 of enlarged region 22. Corrugations 27, 27′, 27″ may be used alone or in combination with one or both of tapered side walls 23, 23′ and mixing structures 24.

Corrugations 27, 27′, 27″ may increase folding within a sample or sample solution, thereby enhancing the reaction kinetics between an analyte in a sample or sample solution and capture molecules 56 of a specific binding assay apparatus 50 (FIGS. 12 and 13) with which microfluidic platform 10 is used.

Microfluidic platforms 10 that incorporate teachings of the present invention may be formed separately from a substrate that comprises specific binding assay apparatus 50 (FIGS. 10 and 11) and subsequently assembled therewith and secured thereto, or they may be formed on or integrally with a specific binding assay apparatus 50.

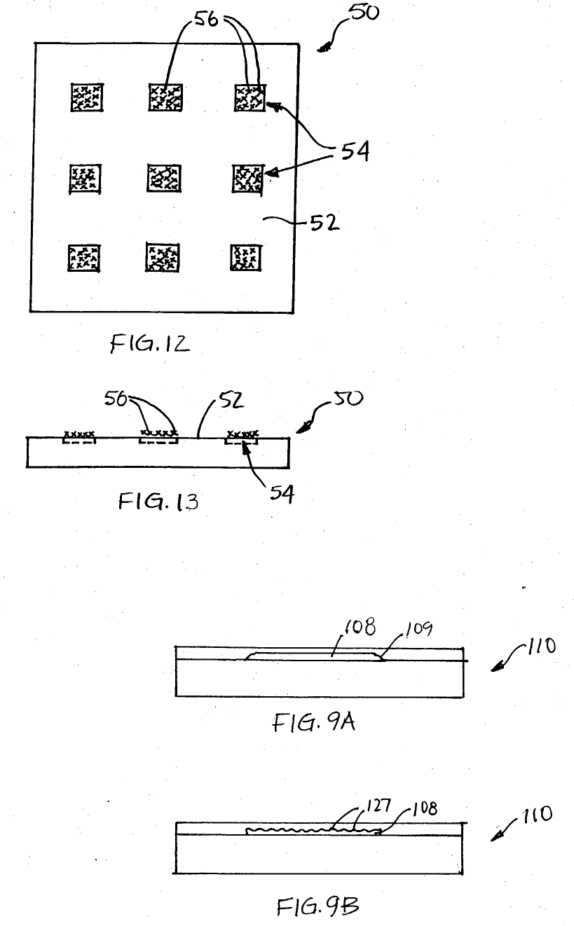

An exemplary embodiment of a method for fabricating a microfluidic platform 10 is depicted in FIGS. 7 through 10. FIGS. 7 and 8 depict fabrication of a mold 110, or master, while FIGS. 9 and 10 illustrate the formation of a microfluidic platform 10 and assembly thereof with a specific binding assay apparatus 50.

In FIG. 7, a substrate 100 with a substantially planar surface 102 is provided. By way of example only, substrate 100 may comprise a full or partial wafer of silicon or another semiconductor material, or a glass or ceramic structure, or any other suitable substrate material. A layer 104 that includes photoimageable material is applied to substantially planar surface 102 in a desired thickness. By way of example only, the photoimageable material of layer 104 may comprise a photoresist, such as SU-8 2025, available from MicroChem Corp. of Newton, Mass. The photoimageable material may be applied to substantially planar surface by spin coating (e.g., spinning substrate 100 at 1000 rpm for 30 seconds for a layer 104 thickness of about 70 μm to about 85 μm) or any other suitable process.

Additional preparation processes may also be conducted on layer 104. In the example of a photoresist, a soft bake process may be conducted at a temperature (e.g., 65° C. and 95° C.) and for a period of time (e.g., 12 minutes total, including 3 minutes at 65° C. and 9 minutes at 95° C.) to evaporate solvent and to densify the photoresist. Of course, these parameters may be prespecified for the type of photoresist being used (in this case SU-8 2025) and the thickness of layer 104 thereof (in this case about 70 μm to about 85 μm).

Next, as shown in FIG. 8, selected regions 106 of the photoimagable material of layer 104 are at least partially cured to form at least one elongate, nonlinear protrusion 108 on substantially planar surface 102. Continuing with the photoresist example, selective curing may be effected by use of a dark field mask, which is useful with negative photoresists. The photoresist may be exposed to an appropriate dose of radiation, as known. In the case of a layer 104 that includes SU-8 2025 and has a thickness of about 70 μm to about 85 μm, an exposure dose of about 500 to about 600 mJ/cm² may be affected. Of course, the duration for which the photoimageable material of layer 104 is exposed to one or more appropriate wavelengths of radiation is dependent upon the intensity of such radiation. By way of example only, such a dose may be provided with an exposure lamp having an intensity of 20 mW/cm² by exposing the photoimageable material of layer 104 to radiation from the exposure lamp for a duration of about 30 seconds.

When photoresist is used as the photoimageable material of layer 104, a post exposure bake (PEB) may then be conducted, as known, to selectively cross-link selected regions 106 of layer 104. An exemplary PEB process for SU-8 2025 having a thickness of about 70 μm to about 85 μm includes heating the SU-8 2025 to a temperature of about 65° C. for about one minute, then increasing the temperature of the SU-8 2025 to a temperature of about 95° C. for about seven minutes.

Development of a photoresist is then effected, as known. Of course, the developer chemical and the duration of exposure of the photoresist to the developer chemical that is used should be appropriate for the type and thickness of photoresist used. In the SU-8 2025 example, the SU-8 developer available from MicroChem could be used, with the photoresist being exposed to the SU-8 developer for about seven minutes.

Following development of a layer 104 of photoresist, unexposed photoimageable material of layer 104 may then be removed from substantially planar surface 102 of substrate 100, as known in the art. The photoimageable material may then be hard baked, as known, if desired. Hard baking may be effected to further cross-link the material that forms protrusion 108. When SU-8 2025 is used to form protrusion 108, hard baking may be effected at a temperature of about 150° C. to about 200° C.

When features such as those depicted in FIGS. 5 through 6B are to be formed in a microfluidic platform 10 (FIGS. 1 and 2) that incorporates teachings of the present invention, these processes may be repeated a plurality of times to form protrusions 108 that include a plurality of superimposed sublayers (not shown) having different configurations that will facilitate the formation of one or more protrusions 108 that have tapered, curved, or other types of nonlinear edges 109 (i.e., edges 109 which are not oriented perpendicularly to the major plane of the mold 110), as shown in FIG. 9A or that will facilitate the formation of corrugations 127 on protrusions 108, as shown in FIG. 9B.

Alternatively, a protrusion 108 with nonlinear or nonperpendicularly oriented edges 109 may be formed by controlling the photolithography process, such as by over exposing, under exposing, over developing, or under developing desired regions of the photoimageable material of layer 104.

As another alternative, the exposed and developed photoimageable material of layer 104 may be etched or otherwise treated, as known in the relevant art, to form protrusions 108 with nonlinear or nonperpendicularly oriented edges 109. Of course, the etchants or other treatment processes that are used must be suitable for the photoimageable material from which layer 104 is formed. Such etching or treatment may be conducted either before or after the exposed and developed photoimageable material of layer 104 is hard baked.

As an alternative to the use of a photoresist as the photoimageable material of layer 104, stereolithographic processes may be used, in which selected regions 106 of layer 104 are selectively exposed to curing radiation (e.g., a UV laser beam) to cure the same, as known, to form protrusion 108.

The shape, dimensions, and pathway of each protrusion 108 are configured to form a corresponding channel 18 (FIGS. 1 and 2) of a microfluidic platform 10 having a complementary shape, complementary dimensions, and a complementary pathway, as desired for use with a particular specific binding assay apparatus 50 (FIGS. 12 and 13).

Of course, other processes may also be used to form protrusion 108 on substantially planar surface 102 of substrate 100, such as the micromachining processes (e.g., masking and etching) that are commonly used in the fabrication of semiconductor devices). When such micromachining processes are used, nonlinear or nonperpendicularly oriented edges 109 may be formed on protrusions by known processes, such as the use of isotropic etchants, facet etching processes, or the like.

Turning now to FIG. 9, once mold 110 has been formed, a layer of conformable material may be placed thereon and at least partially cured, or polymerized, to form microfluidic platform 10. As an example, polydimethylsiloxane (PDMS) may be introduced onto mold 110, degassed in a vacuum, and exposed to a temperature of about 60° C. for about two hours to about three hours to cure the same.

Once microfluidic platform 10 has been formed, it may be removed from mold 110, as depicted in FIG. 10. Surfaces of microfluidic platform 10 and a complementary specific binding assay apparatus 50 (FIGS. 12 and 13) that are to contact one another may then be cleaned.

Next, as shown in FIG. 11, microfluidic platform 10 may be positioned over and aligned and assembled with a complementary specific binding assay apparatus 50, with enlarged regions 22 of channel 18 being oriented adjacent to an in communication with sensing zones 54 of specific binding assay apparatus 50. Other elements of a biosensor system, including, without limitation, excitation sources (e.g., lights), detectors (e.g., charge-coupled detectors (CCDs)), sample delivery conduits, and the like, may then be assembled or otherwise associated with the resulting structure to facilitate use thereof in specific binding assays.

As an alternative, a microfluidic platform 10 that includes side walls 23′ that are oriented nonperpendicularly to a major plane of microfluidic platform 10, nonlinear side walls 23′, or corrugations 27, 27′, 27″ may include a plurality of superimposed, mutually adhered, contiguous layers that have been separately formed by one of the above-described processes (e.g., photolithography), then aligned and secured to one another, as known in the art (e.g., prior to hard baking the same, with a suitable adhesive, etc.), to form a microfluidic platform 10 having the desired configuration.

Once microfluidic platform 10 has been formed, microfluidic platform or one or more regions thereof (e.g., channel 18) may be passivated to prevent or reduce the likelihood of adsorption of the constituents of a sample of sample solution thereto or the reaction of such constituents therewith. By way of example only, such passivation could be effected by treating microfluidic platform 10 with a passivation chemical such as bovine serum albumin (BSA), PLURONICS® (a tri-block copolymer), acrylic acid (AA), acrylamide (AM), dimethylacrylamide (DMA), 2-hydroxyethylacrylate (HEA), or polyethylene glycol (PEG) monomethoxylacrylate. The passivation chemical may be introduced onto the region or regions of microfluidic platform 10 which are to be passivated (e.g., channel 18) and permitted to remain for a sufficient period of time (e.g., at least one hour). Alternatively, known ultraviolet (UV) graft polymerization processes may be employed to passivate one or more regions of microfluidic platform 10.

Turning now to FIGS. 12 and 13, an exemplary specific binding assay apparatus 50 with which microfluidic platform 10 (FIGS. 1 and 2) may be used is depicted. Specific binding assay apparatus 50 may comprise a waveguide (e.g., planar, cylindrical, etc.) or a substrate carrying an array of waveguides and may be useful in fluorescence type assays or SPR type assays. Alternatively, specific binding assay apparatus 50 may comprise a semiconductor-based assay apparatus to which capture molecules have been secured. Microfluidic platform 10 may also be used with any other type of specific binding assay apparatus that may be used to detect analytes in samples or sample solutions that have very small volumes (e.g., volumes on the order of about a nanoliter (10⁻⁹ L) or less).

As depicted, specific binding assay apparatus 50 includes a reaction surface 52 with a plurality of sensing zones 54 arranged thereon in discrete locations. Each sensing zone 54 includes capture molecules 56 (e.g., proteins, peptides, nucleotides, etc.) that have been directly or indirectly immobilized to reaction surface 52, as known in the art. Different sensing zones 54 may include capture molecules 56 with different analyte-binding specificities, or a plurality of different sensing zones may include the capture molecules 56 with the same analyte-binding specificity. When a microfluidic platform 10 according to the present invention is used with specific binding assay apparatus 50, detection of one or more analytes may be effected at each zone with a relatively small number of analyte molecules (e.g., 10,000 or less, 1,000 or less, etc.). Accordingly, each sensing zone 54 may include a correspondingly small number of immobilized capture molecules 56. The number of capture molecules bound at each sensing zone of a specific binding assay apparatus may be optimized or minimized based on the flow characteristics of a sample or sample solution through the microfluidic channel.

Although specific binding assay apparatus 50 is depicted as including a 3×3 array of sensing zones 54, a microfluidic platform 10 according to the present invention may be used with specific binding assay apparatus that include arrays of sensing zones 54 with different organizations (e.g., other than area arrays and arrays that are not square, such as random, pseudorandom, and hexagonal arrays), as well as smaller or much larger arrays (e.g., 30×30 and larger) of sensing zones 54.

In use of microfluidic platform 10 with a specific binding assay apparatus 50, a sample or sample solution is introduced into a channel 18 of microfluidic platform 10 (FIGS. 1 and 2) and permitted to flow therethrough, such as by capillary action or by application of a positive or negative pressure to channel 18. As the sample or sample solution flows along the length of channel 18, the constituents of the sample or sample solution, including any analytes therein, come into contact with capture molecules 56 (FIG. 13) that have been immobilized relative to reaction surface 52 of specific binding assay apparatus at one or more sensing zones 54 thereof. As analyte molecules within the sample or sample solution come into contact with corresponding capture molecules 56 at one or more sensing zones 54, capture molecules 56 bind, by affinity interaction, their corresponding analytes.

Detection of such binding may then be effected by known processes. For example, if a direct, sandwich-type assay is to be performed, a tagged molecule (e.g., an antibody that has been tagged, or labeled, with a fluorescent dye or metal particle) that will specifically bind to each captured analyte may be introduced into channel 18, flow therealong, and be permitted to bind to the analyte. The tag may then be stimulated into excitation and the excitation detected and correlated with an amount of analyte present in the sample or sample solution or simply with the presence or absence of the analyte in the sample or sample solution. Alternatively, the use of polymers to detect binding, or hybridization, of an analyte with a capture molecule may be used. Such processes are described in Boissinot, M, et al., “Detection of Nucleic Acids Using Novel Polymers Able to Transduce Hybridization into Optical or Electrical Signal,” Micro Total Analysis Systems Conference, 2001, pages 319-20, the disclosure of which is hereby incorporated in its entirety by this reference.

As another example, a competitive binding-type assay of a type known in the art may be performed. In a competitive binding assay, tagged molecules that compete with a particular analyte for binding sites on capture molecules 56 are added to the sample or sample solution before introduction thereof into channel 18. Because these tagged molecules compete with corresponding analyte molecules to bind to corresponding capture molecules 56, the amount of the tag detected at a sensing zone 54 is inversely proportional to the amount of analyte in the sample or sample solution. Competitive binding assays are useful for detecting the binding of analytes by corresponding capture molecules 56 in real-time, as such binding occurs, or close to real-time.

As another alternative, when SPR is used to detect the amount or presence or absence of analytes in a sample or sample solution, each sensing zone 54 of specific binding assay apparatus 50 may include a cluster of metallic nanoparticles to which capture molecules 56 are tethered. As a sample or sample solution flows along the length of microfluidic channel 18 (FIGS. 1 and 2) and is introduced to each sensing zone 54, analyte, if any, within the sample or sample solution may specifically bind to capture molecules 56 in that sensing zone 54. An optically-transduced signal, which has an intensity that corresponds to the number of bound analyte molecules, may then be detected, as known in the art. Binding may be detected in real-time or close to real-time, as binding of analyte molecules by capture molecules 56 occurs.

Although the foregoing description contains many specifics, these should not be construed as limiting the scope of the present invention, but merely as providing illustrations of some of the presently preferred embodiments. Similarly, other embodiments of the invention may be devised which do not depart from the spirit or scope of the present invention. Moreover, features from different embodiments of the invention may be employed in combination. The scope of the invention is, therefore, indicated and limited only by the appended claims and their legal equivalents, rather than by the foregoing description. All additions, deletions, and modifications to the invention, as disclosed herein, which fall within the meaning and scope of the claims are to be embraced thereby.

What is claimed is:

1. A microfluidic platform, comprising:
a substantially planar substrate; and
at least one elongate, nonlinear channel formed in an opening to a major surface of said substantially planar substrate, said at least one elongate, nonlinear channel configured to communicate with a plurality of sensing zones of a specific binding assay apparatus upon assembly of the microfluidic platform with the specific binding assay apparatus.

2. The microfluidic platform of claim 1, wherein said substantially planar substrate comprises a material that is optically transparent to at least one wavelength of radiation to be used in the specific binding assay apparatus.

3. The microfluidic platform of claim 1, wherein said such substantially planar substrate comprises a material that will not substantially adsorb analytes from a sample or sample solution to be introduced into said at least one elongate, nonlinear channel.

4. The microfluidic platform of claim 1, wherein said substantially planar substrate comprises a material that will not chemically react with an analyte of a sample or sample solution to be introduced into said at least one elongate, nonlinear channel.

5. The microfluidic platform of claim 1, wherein said at least one elongate, nonlinear channel has a substantially constant depth.

6. The microfluidic platform of claim 1, wherein said at least one elongate, nonlinear channel has a substantially uniform width along the length thereof.

7. The microfluidic platform of claim 1, wherein said at least one elongate, nonlinear channel includes a plurality of discrete, enlarged regions along the length thereof and a transport region between adjacent enlarged regions of said plurality of discrete, enlarged regions.

8. The microfluidic platform of claim 7, wherein each enlarged region of said plurality of discrete, enlarged regions has a width greater than each said transport region.

9. The microfluidic platform of claim 8, wherein a width of each said transport region is substantially uniform along a length thereof.

10. The microfluidic platform of claim 1, wherein said at least one elongate, nonlinear channel has a depth of at least about 25 microns.

11. The microfluidic platform of claim 10, wherein said at least one elongate, nonlinear channel has a depth of about 70 microns or greater.

12. The microfluidic platform of claim 7, wherein each said transport region has a width of at most about 250 microns.

13. The microfluidic platform of claim 12, wherein each said transport region has a width of at most about 25 microns.

14. The microfluidic platform of claim 7, wherein each enlarged region of said plurality of enlarged regions has a width of at most about 1 millimeter.

15. The microfluidic platform of claim 14, wherein each enlarged region of said plurality of enlarged regions has a width of at most about 100 microns.

16. The microfluidic platform of claim 1, wherein said at least one elongate, nonlinear channel has a serpentine configuration.

17. The microfluidic platform of claim 16, wherein said serpentine configuration is configured to bring said at least one elongate, nonlinear channel into communication with a plurality of sensing zones of a specific binding assay apparatus that are arranged in an area array.

18. The microfluidic platform of claim 1, wherein at least a portion of a side wall of said at least one elongate, nonlinear channel is oriented nonperpendicularly relative to a major plane of said substantially planar substrate.

19. The microfluidic platform of claim 18, wherein at least said portion of said side wall tapers outward from a ceiling of said at least one elongate, nonlinear channel to a surface of said substantially planar substrate to which said at least one elongate, nonlinear channel opens.

20. The microfluidic platform of claim 18, wherein at least said portion comprises a plurality of portions, each of which is located so as to communicate with each of said plurality of sensing zones.

21. The microfluidic platform of claim 1, wherein at least a portion of a ceiling of said at least one elongate, nonlinear channel comprises corrugations.

22. The microfluidic platform of claim 21, wherein said corrugations are positioned so as to be located over each of said plurality of sensing zones.

23. A biosensor, comprising:
a specific binding assay apparatus including a plurality of sensing zones on a surface thereof; and
a microfluidic platform including at least one elongate, nonlinear channel communicating with at least some of said plurality of sensing zones.

24. The biosensor of claim 23, wherein said specific binding assay apparatus comprises at least one of a planar waveguide and a cylindrical waveguide.

25. A method for fabricating a microfluidic platform for use with a specific binding assay apparatus, comprising:
providing a substrate that includes a planar surface;
forming at least one elongate, nonlinear protrusion on said planar surface;
introducing a conformable material onto said planar surface and over said at least one elongate, nonlinear protrusion;
at least partially curing said conformable material; and
following said at least partially curing, removing said conformable material from said planar surface and said at least one elongate, nonlinear protrusion.

26. The method of claim 25, wherein said forming comprises forming at least one serpentine protrusion on said planar surface.

27. The method of claim 25, wherein said forming comprises patterning said planar surface.

28. The method of claim 25, wherein said forming comprises:
introducing a layer of photoimageable material onto said planar surface;
selectively curing regions of said layer to form said at least one elongate, nonlinear protrusion; and
removing uncured regions of said layer from said planar surface.

29. The method of claim 28, wherein said introducing said photoimageable material comprises introducing at least one layer comprising a photoresist onto said planar surface and wherein said selectively curing includes exposing and developing regions of said photoresist to form said at least one elongate, nonlinear protrusion.

30. The method of claim 28, further comprising repeating said introducing and said selectively curing at least once.

31. The method of claim 25, wherein said at least partially curing comprises polymerizing said conformable material.

32. A method for fabricating a biosensor, comprising:
providing a specific binding assay apparatus comprising a plurality of sensing zones on a surface thereof; and
positioning a microfluidic platform adjacent said surface with at least one elongate, nonlinear channel of said microfluidic platform being in alignment with at least some of said plurality of sensing zones; and
adhering said microfluidic platform to said surface of said specific binding assay apparatus.

33. The method of claim 32, wherein said providing comprises providing said specific binding assay apparatus with capture molecules immobilized at at least some of said plurality of sensing zones.

34. The method of claim 32, wherein said adhering is effected by a material of said microfluidic platform.
